(19) United States
(12) Patent Application Publication
(10) Pub. No.: US 2026/0322380 A1
(43) Pub. Date: Oct. 15, 2026

(54) High-Throughput Adiabatic Logic System and Method

(71) Applicant: Bitdeer, Inc., San Jose, CA (US)

(72) Inventor: Stephen M. Beccue, Salmon, ID (US)

(21) Appl. No.: 19/176,660

(22) Filed: Apr. 11, 2025

(51) Int. Cl. H03K 19/00

(52) U.S. Cl. CPC H03K 19/0019

(57) ABSTRACT

A high-throughput adiabatic logic system includes a pipeline of N adiabatic logic gates, where N is an integer and N≥5, and an N-phase power clock generator. Every two consecutive power clock phases are offset by a phase difference less than one quarter the power clock period, and the N-phase power clock generator generates the N-phase power clock phases such that their evaluation and charge recovery slopes dV/dt are, preferably, no steeper than the evaluation and charge recovery slopes dV/dt of the four power clock phases used in a conventional four-phase adiabatic logic system. The high-throughput adiabatic logic system performs more computations per period than the conventional four-phase adiabatic logic system and without sacrificing energy efficiency.

### BACKGROUND OF THE INVENTION

Adiabatic logic is a low-power alternative to static CMOS that uses reversible logic to conserve energy. FIG. 1 is a schematic drawing of the salient features of a conventional adiabatic logic system 100. The adiabatic logic system 100 consists of four cascaded adiabatic logic gates 102, 104, 106 and 108 and a four-phase power clock generator 110. The four-phase power clock generator generates a periodic four-phase trapezoidal power clock consisting of four power clock phases P1, P2, P3 and P4. Each of the power clock phases P1, P2, P3 and P4 supplies power to and controls the operation of a corresponding one of the adiabatic logic gates 102, 104, 106 and 108. As illustrated in the timing diagram in FIG. 2, all power clock phases P1, P2, P3 and P4 have the same period T and are successively shifted in time by a fixed phase difference 210 of one quarter the period T. In other words, the four power clock phases P1, P2, P3 and P4 are in quadrature. FIG. 2 further highlights how each period of each power clock phase P1, P2, P3 and P4 has evaluation (E), hold (H), charge recovery (R) and wait (W) intervals.

Data in the adiabatic logic system 100 is processed in a pipeline fashion. Specifically, when one of the adiabatic logic gates 102, 104, 106 or 108, say the second adiabatic logic gate 104, is operating within the E interval of its corresponding power clock phase, the first adiabatic logic gate 102 is operating in its H interval, thereby giving the second adiabatic logic gate 104 sufficient time to capture at its inputs output data produced by the first adiabatic logic gate 102. Meanwhile, the third adiabatic logic gate 106 is operating in its W interval, waiting for the R interval of the fourth adiabatic logic gate 106 to end before commencing operation in its E interval, which begins just as the H interval of the second adiabatic logic gate 104 begins.

Various adiabatic logic families have been proposed over the years, two of the most common being Efficient Charge Recovery Logic (ECRL) and Positive Feedback Adiabatic Logic (PFAL). A schematic drawing of a basic ECRL NOT gate (i.e., inverter) 300 is shown in FIG. 3. Its operation over one full cycle can be explained as follows. Assuming that an input logic high is applied to input terminal IN at the start of the cycle, NMOS transistor 306 turns on, pulling output node OUT to ground, in other words, to an output logic low. The complementary input logic low applied to complementary input terminal node I̅N̅, causes NMOS transistor 308 to remain off over the entire cycle. As the power clock P2 ramps up during the evaluation interval, it eventually exceeds |V_{th,p}|, where V_{th,p} is the threshold voltage of PMOS transistor 304, causing PMOS transistor 304 to turn on. (Note: The time Δt_{E} that expires before PMOS transistor 304 is able to turn on and the time 212 during which the adiabatic logic gate 300 is functionally able to evaluate its inputs are both shown in the timing diagram in FIG. 2.) Once PMOS transistor 304 has turned on, the voltage on complementary output node O̅U̅T̅ begins tracking the voltage of the ramping-up power clock P2. It is ultimately pulled up to plateau voltage Vdd, corresponding to an output logic high, at the end of the evaluation interval. The output logic low on output node O̅U̅T̅ and the output logic high on complementary output node OUT are then held for the duration of the hold interval, to be used as inputs for evaluation by the next adiabatic logic gate in the pipeline.

After the hold interval ends the power clock P2 is then ramped back down to ground during the charge recovery interval. During this time the charge that accumulated and was stored in the output load capacitors of the adiabatic logic gate 300 during the evaluation and hold intervals is recycled back to the energy reservoir of the four-phase power clock generator 110, via PMOS transistor 304. Not all of the charge is able to be recycled back, due to the non-zero threshold voltage V_{th,p} of PMOS transistor 304, which turns off when the voltage of the power clock P2 becomes less than |V_{th,p}|. Nevertheless, recycling a significant portion of the accumulated charge back to the four-phase power clock generator 110 enhances the energy efficiency of the adiabatic logic gate 300. (Note: The time Δt_{R} that PMOS transistor 304 is unable to recycle charge back to the power clock generator 210 and the time 214 during which the adiabatic logic gate 300 is functionally able to recycle the charge back to the power clock generator 210 are both shown in the timing diagram in FIG. 2.)

The final quarter cycle, in other words the wait interval, is included each of the four power clock phases P1, P2, P3 and P4 mostly for symmetry reasons, given that generating symmetric power clocks is both simpler and more energy efficient than generating asymmetrical power clocks.

The energy efficiency of the conventional four-phase adiabatic logic system 100 is no doubt a desirable attribute. However, there are limits on how fast it can process data. Computational throughput can be increased by reducing the period T of the four-phase power clocks P1, P2, P3 and P4 (i.e., by increasing their frequency), however such an approach is undesirable since achieving high energy efficiency requires that the slopes dV/dt of the evaluation and charge recovery intervals be gradual, but reducing the period T of the four-phase power clock P1, P2, P3 and P4 would result in steeper dV/dt evaluation and charge recovery intervals, thus compromising the energy efficiency of the adiabatic logic system 100. What is needed, therefore, is an adiabatic logic system that achieves a high computational throughput but which does so without having to sacrifice energy efficiency.

### BRIEF SUMMARY OF THE INVENTION

A high-throughput adiabatic logic system and method are disclosed. The high-throughput adiabatic logic system includes a pipeline of N adiabatic logic gates, where Nis an integer and N≥5, and an N-phase power clock generator. Every two consecutive power clock phases are offset by a phase difference less than one quarter the power clock period, and the N-phase power clock generator generates the N-phase power clock phases such that their evaluation and charge recovery slopes dV/dt are, preferably, no steeper than the evaluation and charge recovery slopes dV/dt of the four power clock phases used in a conventional four-phase adiabatic logic system. The high-throughput adiabatic logic system performs more computations per period than the conventional four-phase adiabatic logic system and without sacrificing energy efficiency.

Further features and advantages of the invention, including a detailed description of the above-summarized and other exemplary embodiments of the invention, will now be described in detail with respect to the accompanying drawings, in which like reference numbers are used to indicate identical or functionally similar elements.

### BRIEF DESCRIPTION OF THE DRAWINGS

FIG. 1 is a schematic drawing of a conventional four-phase adiabatic logic system;

FIG. 2 is timing diagram of the four-phase power clock P1, P2, P3, P4 used to control and supply power to the conventional four-phase adiabatic logic system depicted in FIG. 1;

FIG. 3 is a schematic drawing of a basic Efficient Charge Recovery Logic (ECRL) buffer/inverter;

FIG. 4 is a schematic drawing of a five-phase adiabatic logic system, according to one embodiment of the present invention;

FIG. 5 is a timing diagram of the five-phase power clock used to supply power and control the operation of the five-phase adiabatic logic system, in accordance with one embodiment of the present invention;

FIG. 6 is a block diagram of a five-phase stepwise power clock generator that may be used to implement the five-phase power clock generator of the five-phase adiabatic logic system depicted in FIG. 4, according to one embodiment of the present invention;

FIG. 7 is a schematic drawing of one of the unit capacitor cells used in the five-phase stepwise power clock generator depicted in FIG. 6;

FIG. 8 is a drawing depicting a series of snapshots of the five-phase stepwise power clock generator depicted in FIGS. 6 and 7, highlighting how various switches in the five-phase stepwise power clock generator are controlled in the process of generating the first power clock phase P1 of the five-phase power clock; and

FIG. 9 is a timing diagram of a five-phase power clock generated by the stepwise power clock generator depicted in FIGS. 6 and 7, for a circumstance in which the stepwise power clock generator is constructed from five unit capacitor cells.

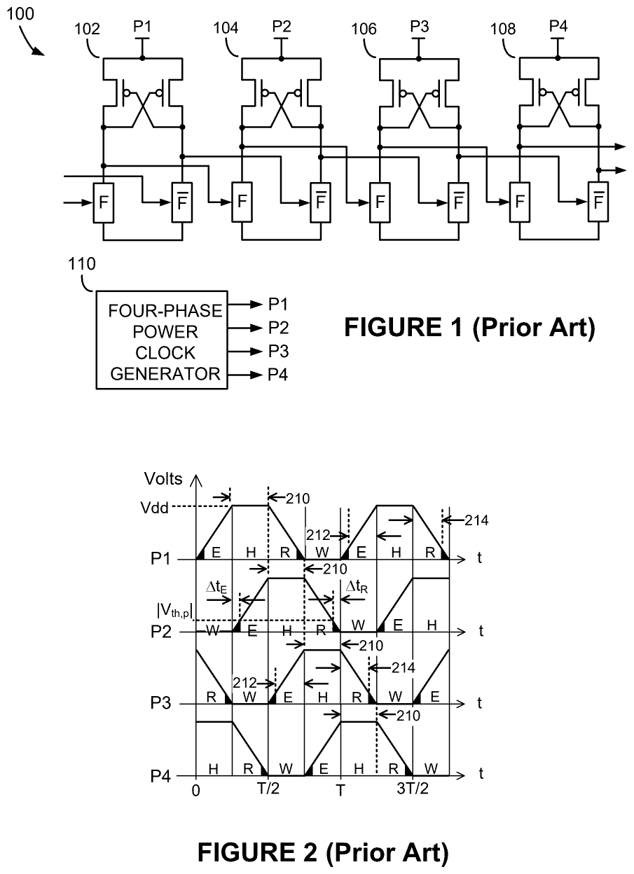

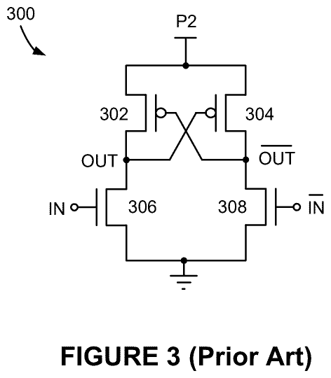

### DETAILED DESCRIPTION

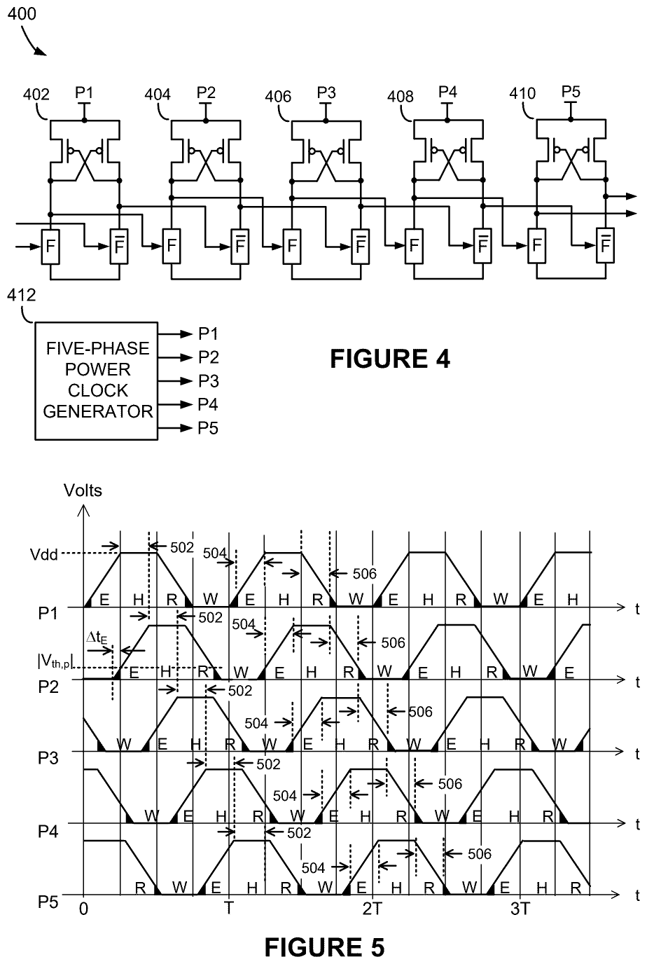

Referring to FIG. 4 there is shown a five-phase adiabatic logic system 400, according to one embodiment of the present invention. The five-phase adiabatic logic system 400 comprises first, second, third, fourth and fifth adiabatic logic gates 402, 404, 406, 408 and 410 and a five-phase power clock generator 412. The five-phase power clock generator 412 is configured to generate a five-phase trapezoidal power clock, comprising five power clock phases P1, P2, P3, P4 and P5. The five power clock phases P1, P2, P3, P4 and P5 supply power to and control the operation of the adiabatic logic gates 402, 404, 406, 408 and 410.

Before continuing it should be made clear what the term “adiabatic” means in the context of the present invention. In general, the term “adiabatic” refers to a thermodynamic process in which no heat or energy is exchanged between the system and the external environment. Although no electronic circuit (the “system” in this case) can be fully adiabatic, since any practical circuit must always dissipate some heat to the surrounding environment, it should be appreciated and understood, as it is appreciated understood by those of ordinary skill in the pertinent art, that the term “adiabatic” is nevertheless often and routinely used in the low-power electronic arts to refer to classes of electronic circuits and systems that use charge recovery logic (also referred to as “reversible logic”) to conserve energy. That same convention and meaning of the word “adiabatic” is used in the following detailed description of the present invention, and should also be recognized, appreciated, and understood when construing any appended claim that includes the word “adiabatic.”

As illustrated in the timing diagram in FIG. 5, the five-phase trapezoidal power clock takes advantage of the times Δt_{E} in the evaluation intervals during which the PMOS transistors in the adiabatic logic gates 402, 404, 406, 408 and 410 are functionally unable to evaluate their inputs (due to the non-zero threshold voltage V_{th,p} of the PMOS transistors). As these times Δt_{E} are extraneous, the five power clock phases P1, P2, P3, P4 and P5 in effect ignore them, resulting in the five power clock phases P1, P2, P3, P4 and P5 overlapping during these times Δt_{E}, with a phase difference 502 between successive power clock phases of less than one quarter of the period T.

Compared to a conventional four-phase adiabatic logic system in which the four power clock phases P1, P2, P3 and P4 have the same amplitude and period as the five power clock phases P1, P2, P3, P4 and P5 in the five-phase adiabatic logic system 400, the times 504 during which the PMOS transistors in the adiabatic logic gates 402, 404, 406, 408 and 410 are functionally able to evaluate their inputs is no shorter than the times 212 during which the adiabatic logic gates 102, 104, 104 and 106 in the four-phase adiabatic logic system 100 are functionally able to evaluate their inputs. (Compare FIGS. 2 and 5, and assume the amplitude and period T are the same in both drawings.) Further, and again compared to a four-phase adiabatic logic system in which the four power clock phases P1, P2, P3 and P4 have the same amplitude and period as the five power clock phases P1, P2, P3, P4 and P5 in the five-phase adiabatic logic system 400, the times 506 during which the PMOS transistors in the adiabatic logic gates 402, 404, 406, 408 and 410 are functionally able to recycle charge back to the five-phase power clock generator 412 is no shorter than the times 214 during which the adiabatic logic gates 102, 104, 104 and 106 are functionally able to recycle charge back to their four-phase power clock generator 110. In other words, assuming that the amplitudes and period T of the power clock phases are the same in both FIGS. 2 and 5, the dV/dt slopes in the evaluation and charge recovery intervals in FIG. 5 remain substantially unchanged from the dV/dt slopes in the evaluation and charge recovery intervals in FIG. 2. Therefore, for power clocks of the same amplitude and period, the five-phase adiabatic logic system 400 is more computationally proficient, capable of performing 20% more computations per period T than the conventional four-phase adiabatic logic system 100 and, importantly, without having to sacrifice energy efficiency.

If desired, even more power clock phases can be introduced to further increase the computational throughput. The additional power clock phases can be generated by simply modifying the five-phase power clock generator 412 so that it produces the additional power clock phase(s) and adding the necessary additional adiabatic logic gate(s) to the pipeline. If modified to generate six power clock phases, for example, the resulting six-phase adiabatic logic system would then be capable of performing 33% more computations per period T than the conventional four-phase adiabatic logic system 100, again without incurring a power penalty.

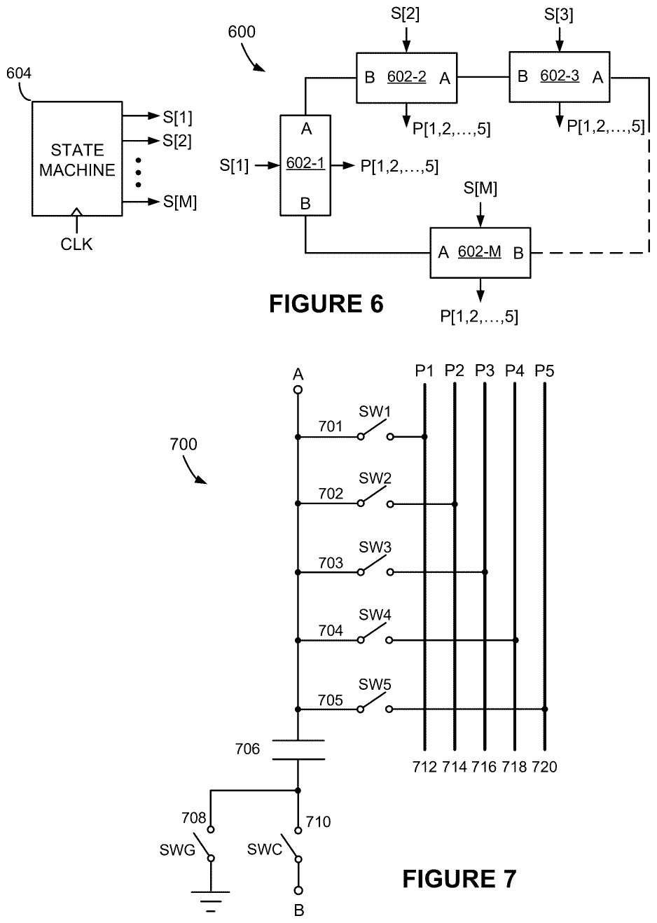

The five-phase power clock generator 412 for the five-phase adiabatic logic system 400 can be implemented in various ways. For example, a ring oscillator, multiple phase-locked loops (PLLs), a driven set of delays lines, or a plurality of LC oscillators can be used. While any one of these approaches can be used, in a preferred embodiment of the present invention a stepwise power clock generator 600 like that depicted in FIG. 6 is used. The stepwise power clock generator 600 is based on the model switched-capacitor clock synthesizer disclosed in co-pending and commonly-assigned U.S. patent application Ser. No. 19/176,438, entitled “Switched-Capacitor Clock Synthesizer for Nonlinear Loads,” which is incorporated herein by reference.

As shown in FIG. 6, the stepwise power clock generator 600 comprises a plurality of unit capacitor cells 602-1, 602-2, 602-3, . . . ,602-M configured in a loop, where M denotes the number of unit capacitor cells used. Each unit capacitor cell 602-1, 602-2, 602-3, . . . ,602-M has a first unit capacitor cell terminal (labeled terminal “A” in FIG. 6) and a second unit capacitor cell terminal (labeled terminal “B”) so that when configured in the loop terminal A of any given unit capacitor cell is coupled to terminal B of an adjacent unit capacitor cell. The unit capacitor cells 602-1, 602-2, 602-3, . . . ,602-M are controlled by a corresponding plurality of switch control sets S[1], S[2], S[3], . . . , S[M] generated and provided by a state machine 604, and the unit capacitor cells 602-1, 602-2, 602-3, . . . ,602-M are collectively operable to generate the five power clock phases P1, P2, P3, P4 and P5.

FIG. 7 is a schematic drawing illustrating in more detail how each of the unit capacitor cell 602-1, 602-2, 602-3, . . . ,602-M is constructed in one embodiment of the invention. As shown, each unit capacitor cell 700 comprises first, second, third, fourth and fifth output switches 701, 702, 703, 704 and 705; a capacitor 706; a ground-connect switch 708; and a loop switch 710. A first terminal of the capacitor 706 is connected to the first unit capacitor cell terminal (i.e., terminal A), and a second terminal of capacitor 706 is selectively coupled to the second unit capacitor cell terminal (i.e., terminal B), depending on whether loop switch 710 is open (i.e., is “off”) or closed (i.e., is “on”).

The first, second, third, fourth and fifth output switches 701, 702, 703, 704 and 705 are coupled between the first terminal of capacitor 706 and corresponding output signal buses 712, 714, 716, 718 and 720 or, alternatively, between the second terminal of capacitor 706 and the corresponding output signal buses 712, 714, 716, 718 and 720. Further, the first, second, third, fourth and fifth output switches 701, 702, 703, 704 and 705 are controlled by corresponding output-switch control signals SW1-SW5. Ground-connect switch 708 is coupled between the second terminal of capacitor 706 and ground, and is controlled by ground-connect switch control signal SWG. Loop switch 710 is also connected to the second terminal of capacitor 706, and is controlled by loop-switch control signal SWC.

When a plurality of unit capacitors cells 700 is configured in a loop, as in FIG. 6, one of the ground-connect switches 708 in a given one of the unit capacitor cells 700-1, 700-2, . . . ,700-M is closed, thereby establishing a ground reference for the stepwise power clock generator 600, and the loop switch 710 in the given unit capacitor cell remains open, connecting terminal B of the given unit capacitor cell to terminal A of its adjacent unit capacitor cell. Meanwhile, the ground-connect switches 708 in all remaining unit capacitor cells remain open and the loop switches 710 in all remaining unit capacitor cells remain closed, thereby effectively connecting all capacitors 706-1,706-2, . . . ,706-M in the plurality of the unit capacitors cells 700-1, 700-2, . . . ,700-M in series. The resulting capacitor bank is periodically charged and refreshed by an external power supply so that the capacitor bank optimally maintains a voltage across it of Vdd and so that each of the capacitors 706-1, 706-2, . . . , 706-M in the capacitor bank optimally maintains a voltage drop of Vdd/M.

The stepwise power clock generator 600 is operable to generate five stepwise trapezoidal power clock phases P1, P2, P3, P4 and P5 on output signal buses 712, 714, 716, 718 and 720, with successive phases having a phase difference 502 determined by the threshold voltage V_{th,p} of the PMOS transistors in the adiabatic logic gates 402, 404, 406, 408 and 410, and allot evaluation and charge recovery times 504 and 506, as shown in FIG. 5. Note that the output signal buses 712, 714, 716, 718 and 720 are shared by, in other words, are common among, the plurality of the unit capacitors cells 700-1, 700-2, . . . ,700-M.

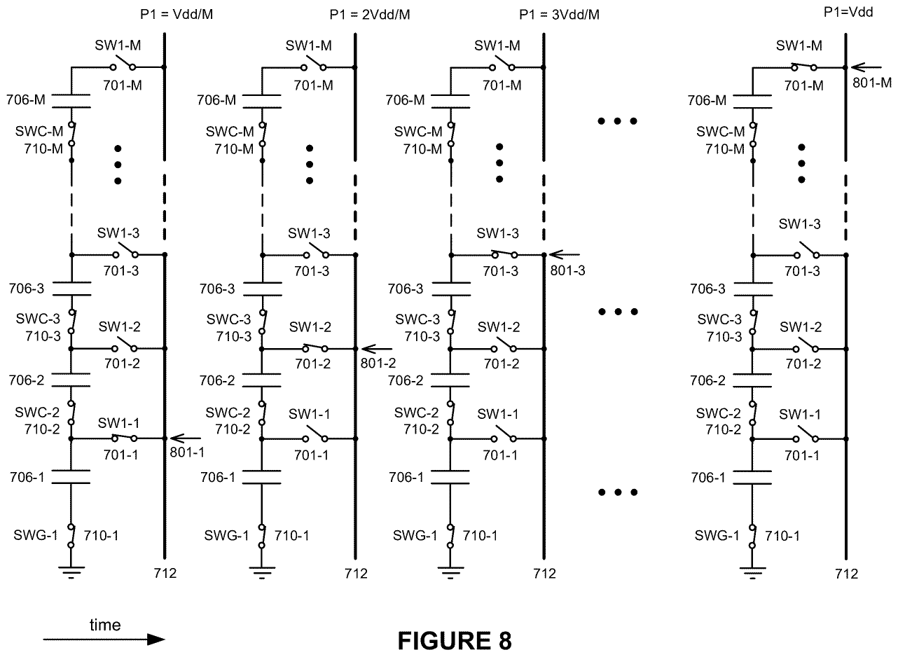

FIG. 8 is a drawing illustrating in a series of snapshots how first output switches 701-1, 701-2, . . . , 701-M in the plurality of unit capacitor cells 700-1, 700-2, . . . ,700-M are controlled in the process of generating the first power clock phase Pl on first-phase output signal bus 712. It is assumed in this example that ground-connect switch 710-1 is closed, thereby making capacitor 706-1 in unit capacitor cell 701-1 the ground reference for the capacitor bank. During operation, first-output switches 701-1, 701-2, . . . ,701-M in unit capacitor cells 700-1, 700-2, . . . ,700-M are closed and opened in sequence (see reference arrows 801-1, 801-2, 801-3, . . . 801-M in FIG. 8), under the control of first-phase switch control signals SW1-1, SW1-2, . . . ,SW1-M, thereby cumulatively increasing the number of capacitors 706-1, 706-2, . . . , 706-M that are coupled in series between first-phase output signal bus 712 and ground. The accumulation of capacitors between the first-phase output signal bus 712 and ground results in the output voltage on first-phase output signal bus 712 ramping up in voltage steps of Vdd/M. When the plateau voltage Vdd is reached, first-output switch 701-M is held closed for a quarter cycle, after which time first-output switches 701-1, 701-2, . . . ,701-M are sequentially closed and opened in a reverse order from that during the ramp-up quarter cycle, thereby successively subtracting the number of capacitors 706-1, 706-2, . . . ,706-M that are coupled in series between first-phase output signal bus 712 and ground and consequently ramping down the output voltage in stepped decrements of Vdd/M. Finally, after the output voltage has reached its minimum, the minimum voltage is held for a quarter cycle. This completes the first full cycle of the first power clock phase P1. The above-described process is repeated indefinitely to thereby produce the desired periodic first power clock phase P1 on first-phase output signal bus 712.

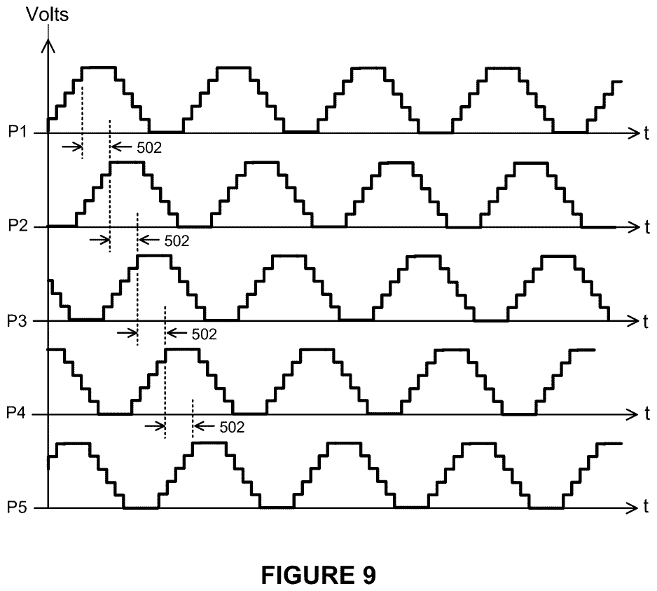

The remaining four power clock phases P2, P3, P4 and P5 are generated similarly but using output switch sets: 702-1, 702-2, . . . ,702-M; 703-1, 703-2, . . . ,703-M; 704-1, 704-2, . . . ,704-M and 705-1, 705-2, . . . ,705-M, each of which is controlled by corresponding switch control sets: SW2-1, SW2-2, . . . ,SW2-M; SW3-1, SW3-2, . . . ,SW3-M; SW4-1, SW4-2, . . . ,SW4-M and SW5-1, SW5-2, . . . ,SW5-M generated and provided by the state machine 604, and each switch control set successively delayed by phase difference 502, as shown in FIG. 5. FIG. 9 is a timing diagram of the five power clock phases P1, P2, P3, P4 and P5 generated by the stepwise power clock generator 600 for a circumstance in which M=5, it being understood that in an actual implementation M would likely be greater than 5. Also highlighted in the drawing is the fact that each two consecutive power clock phases have a phase difference 502 of less than one quarter of the period.

While various embodiments of the present invention have been described, they have been presented by way of example and not limitation. It will be apparent to persons skilled in the relevant art that various changes in form and detail may be made to the exemplary embodiments without departing from the true spirit and scope of the invention. Accordingly, the scope of the invention should not be limited by the specifics of the exemplary embodiments but, instead, should be determined by the appended claims, including the full scope of equivalents to which such claims are entitled.

1. A high-throughput adiabatic logic system, comprising:
a pipeline of N adiabatic logic gates, where N is an integer greater than or equal to five;
an N-phase power clock generator configured to generate N trapezoidal power clock phases that control the pipeline of N adiabatic logic gates,
wherein all of the N trapezoidal power clock phases have the same amplitude and the same period, each period including evaluation, hold, charge recovery and wait intervals, and every two consecutive trapezoidal power clock phases among the N trapezoidal power clock phases are phase-offset by a fixed phase difference less than one quarter of the period.

2. The high-throughput adiabatic logic system of claim 1, wherein the N-phase power clock generator is configured to set the fixed phase difference depending on how long it takes an evaluation voltage ramp during the evaluation intervals to ramp up and exceed an absolute value of a magnitude of a threshold voltage of PMOS transistors in the N adiabatic logic gates.

3. The high-throughput adiabatic logic system of claim 2, wherein the N-phase power clock generator is configured to control and set a slope of the evaluation voltage ramp so that it is no steeper than a slope of an evaluation voltage ramp in a conventional four-phase adiabatic logic system having four power clock phases with the same amplitude and period as the N trapezoidal power clock phases.

4. The high-throughput adiabatic logic system of claim 3, wherein the N-phase power clock generator is configured to control and set a slope of a charge recovery voltage ramp during the charge recovery intervals of the N trapezoidal power clock phases so that it is no steeper than a slope of a charge recovery voltage ramp in a conventional four-phase adiabatic logic system having four power clock phases with the same amplitude and period as the N trapezoidal power clock phases.

5. The high-throughput adiabatic logic system of claim 1, wherein the N-phase power clock generator is configured to allot an evaluation time for each of the N adiabatic logic gates to evaluate its inputs during the evaluation intervals, and the allotted evaluation time is no shorter than an evaluation time during which an adiabatic logic gate in a conventional four-phase adiabatic logic system having four power clock phases of equal period and amplitude is functionally able to evaluate its inputs.

6. The high-throughput adiabatic logic system of claim 5, wherein the N-phase power clock generator is configured to allot a charge recovery time for each of the N adiabatic logic gates to recycle charge back to the N-phase power clock generator during charge recovery intervals, and the allotted charge recovery time is no shorter than a charge recovery time during which an adiabatic logic gate in a conventional four-phase adiabatic logic system having four power clock phases of equal period and amplitude is functionally able to recycle charge back to its four-phase power clock generator.

7. A method of processing data in a high-throughput adiabatic logic system, comprising:
generating N trapezoidal power clock phases, where N is an integer greater than or equal to five, all N trapezoidal power clock phases having the same amplitude and the same period, and each period including evaluation, hold, charge recovery and wait intervals; and
applying the N trapezoidal power clock phases to a pipeline of N adiabatic logic gates,
wherein generating the N trapezoidal power clock phases includes establishing a fixed phase shift between every two consecutive N trapezoidal power clock phases, a duration of the fixed phase shift determined by how long it takes an evaluation voltage ramp to ramp up and exceed an absolute value of a magnitude of a threshold voltage of PMOS transistors in the N adiabatic logic gates.

8. The method of claim 7, wherein the fixed phase shift has a duration less than one quarter of the period.

9. The method of claim 7, wherein generating the N trapezoidal power clock phases includes setting a slope of an evaluation voltage ramp for the evaluation intervals of the N trapezoidal power clock phases, the slope of the evaluation voltage ramp being no steeper than a slope of an evaluation voltage ramp in a conventional four-phase adiabatic logic system having four power clock phases with the same amplitude and period as the N trapezoidal power clock phases.

10. The method of claim 9, wherein generating the N trapezoidal power clock phases further includes setting a slope of a charge recovery voltage ramp for the charge recovery intervals of the N trapezoidal power clock phases, the slope of the charge recovery voltage ramp being no steeper than a slope of a charge recovery voltage ramp in a conventional four-phase adiabatic logic system having four power clock phases with the same amplitude and period as the N trapezoidal power clock phases.

11. The method of claim 7, wherein generating the N trapezoidal power clock phases includes allotting an evaluation time for each N adiabatic logic gate to evaluate its inputs, the allotted evaluation time being no shorter than an evaluation time during which an adiabatic logic gate in a conventional four-phase adiabatic logic system having four power clock phases of equal period and amplitude is functionally able to evaluate its inputs.

12. The method of claim 7, wherein generating the N trapezoidal power clock phases further includes allotting a charge recycle time for each N adiabatic logic gate to recycle charge back to an N-phase power clock generator of the adiabatic logic system, the allotted charge recovery time being no shorter than a charge recovery time during which an adiabatic logic gate in a conventional four-phase adiabatic logic system having four power clock phases of equal period and amplitude is functionally able to recycle charge back to its four-phase power clock generator.
